(19) United States
(12) Patent Application Publication
(10) Pub. No.: US 2025/0087565 A1
(43) Pub. Date: Mar. 13, 2025

(54) WIRING STRUCTURE, SEMICONDUCTOR PACKAGE INCLUDING THE SAME AND MANUFACTURING METHOD FOR THE WIRING STRUCTURE

(71) Applicant: Samsung Electronics Co., Ltd., Suwon-si (KR)

(72) Inventors: Sehoon JANG, Suwon-si (KR); Kyung Don MUN, Suwon-si (KR)

(73) Assignee: Samsung Electronics Co., Ltd., Suwon-si (KR)

(21) Appl. No.: 18/588,460

(22) Filed: Feb. 27, 2024

(30) Foreign Application Priority Data
Sep. 7, 2023 (KR) 10-2023-0118842

(51) Int. Cl. H01L 23/498; H01L 21/48; H01L 21/768; H01L 23/00

(52) U.S. Cl. CPC H01L 23/49822; H01L 21/4857; H01L 21/76871; H01L 24/05; H01L 24/13; H01L 2224/05008; H01L 2224/05025; H01L 2224/13009; H01L 2224/13024; H01L 2924/01028; H01L 2924/1433; H01L 2924/1434; H01L 2924/182

(57) ABSTRACT

A wiring structure may include a wiring layer including a wiring pad, an insulating layer on the wiring layer and covering the wiring layer, a connection pad on the insulating layer, and a via passing through the insulating layer and connecting the wiring pad and the connection pad. The wiring pad may include a first metal layer and a second metal layer on the first metal layer. A bottom surface of the via may abut the first metal layer, and the second metal layer may surround a side surface of the via and may be adjacent to the bottom surface.

### CROSS-REFERENCE TO RELATED APPLICATION

This application claims priority to and the benefit of Korean Patent Application No. 10-2023-0118842, filed in the Korean Intellectual Property Office on Sep. 7, 2023, the entire contents of which are incorporated herein by reference.

### BACKGROUND

### (a) Field

The present disclosure relates to a wiring structure, a semiconductor package including the same, and/or a manufacturing method for the wiring structure.

### (b) Description of the Related Art

In the field of semiconductor packaging technology, package-on-package (POP) structures, in which semiconductor packages are stacked on top of another semiconductor package to form a single package, are widely used for miniaturization of packages, yield improvement, etc.

For example, a POP structure may be formed by disposing a semiconductor chip on a front side redistribution line (FRDL) structure, encapsulating it, forming a back side redistribution line (BRDL) structure on the encapsulated semiconductor chip, and disposing another separately-packaged semiconductor package on the back side redistribution structure.

In such a POP structure, the back side redistribution line structure of the lower semiconductor package may include a wiring layer, an insulating layer that covers the wiring layer, and connection pads that are disposed on the insulating layer and are connected to the wiring layer, etc. In this case, there is a need for a new semiconductor package structure capable of limiting and/or preventing an increase in resistance while improving the adhesion between a wiring layer and an insulating layer in a back side redistribution line structure that electrically connect semiconductor packages.

### SUMMARY

The present disclosure relates to a wiring structure, a semiconductor package including the same, and/or a manufacturing method for the wiring structure capable of improving the adhesion between an insulating layer and a wiring layer.

Further, the present disclosure relates to a wiring structure, a semiconductor package including the same, and/or a manufacturing method for the wiring structure capable of limiting and/or minimizing resistance.

According to an embodiment of the present disclosure, a wiring layer may include a wiring pad; an insulating layer on the wiring layer and covering the wiring layer; a connection pad on the insulating layer; and a via passing through the insulating layer and connecting the wiring pad and the connection pad. The wiring pad may include a first metal layer and a second metal layer on the first metal layer. A bottom surface of the via may abut the first metal layer. The second metal layer may surround a side surface of the via and may be adjacent to the bottom surface of the via.

According to an embodiment of the present disclosure, a semiconductor package may include a first semiconductor package including a first wiring structure, a first semiconductor chip on the first wiring structure and electrically connected to the first wiring structure, a sealing material on the first wiring structure and encapsulating the first semiconductor chip, a second wiring structure on the sealing material, and conductive posts passing through the sealing material and electrically connecting the first wiring structure and the second wiring structure together; and a second semiconductor package on the first semiconductor package and including a second semiconductor chip. The second wiring structure may include a wiring layer including a wiring pad, an insulating layer on the wiring layer and covering the wiring layer, a connection pad on the insulating layer, and a via passing through the insulating layer and connecting the wiring pad and the connection pad together. The wiring pad may include a first metal layer and a second metal layer on the first metal layer. A bottom surface of the via may be in contact with the first metal layer. The second metal layer may surround a side surface of the via adjacent to the bottom surface, and the connection pad may electrically connect the second semiconductor package and the second wiring structure together.

According to an embodiment of the present disclosure, a manufacturing method for a wiring structure may include forming a wiring pad, the wiring pad including a first metal layer and a second metal layer on the first metal layer, the second metal layer exposing a center portion of the first metal layer; forming an insulating layer on the wiring pad; forming a via passing through the insulating layer and connecting to the center portion of the first metal layer; and forming a connection pad on the insulating layer and connected to the via.

According to an aspect of the present disclosure, it is possible to provide a wiring structure, a semiconductor package including the same, and a manufacturing method for the wiring structure capable of improving the adhesion between an insulating layer and a wiring layer.

According to another aspect of the present disclosure, it is possible to provide a wiring structure, a semiconductor package including the same, and a manufacturing method for the wiring structure capable of limiting and/or minimizing resistance.

### BRIEF DESCRIPTION OF THE DRAWINGS

FIG. 1 is a cross-sectional view of a wiring structure according to an embodiment.

FIG. 2 is a cross-sectional view of a wiring structure according to an embodiment.

FIG. 3 is a cross-sectional plan view of the wiring structure shown in FIG. 2, taken along line I-I′.

FIG. 4 is a cross-sectional view of a wiring structure according to an embodiment.

FIG. 5 is a cross-sectional plan view of the wiring structure shown in FIG. 4, taken along line I-I′.

FIG. 6 is a cross-sectional view of a wiring structure according to an embodiment.

FIG. 7 is a cross-sectional plan view of the wiring structure shown in FIG. 6, taken along line I-I′.

FIG. 8 is a cross-sectional view of a semiconductor package according to an embodiment.

FIG. 9 is a cross-sectional view of a semiconductor package according to an embodiment.

FIG. 10 to FIG. 23 are views illustrating wiring structure manufacturing processes according to some embodiments.

### DETAILED DESCRIPTION

In the following detailed description, only certain embodiments of the present disclosure have been shown and described, simply by way of illustration. The present disclosure can be variously implemented and is not limited to the following embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., may be exaggerated for clarity. Further, in the drawings, for understanding and ease of description, the thickness of some layers and areas is exaggerated.

Throughout this specification, when a part is referred to as being “connected” to another part, it may be directly connected to the other part, or may be connected to the other part indirectly with any other elements interposed therebetween. From a similar point of view, when a part is referred to as being “connected” to another part, it may be physically connected to the other part, or may be electrically connected to the other part. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Furthermore, throughout this specification, the ordinal numbers such as first, second, or the like are used to distinguish an element from other elements identical or similar to the corresponding element, and are not necessarily intended to indicate a particular element. Accordingly, an element termed as a first element in a part of this specification may be termed as a second element in other parts of this specification.

Further, throughout this specification, elements expressed in the singular forms are intended to include the plural forms as well unless the context clearly indicates otherwise. For example, an insulating layer may be used to refer to not only one insulating layer but also a plurality of insulating layers, such as two, three, or more.

Furthermore, throughout this specification, one surface and the other surface are intended to distinguish between different surfaces, and are not intended to be limited to specific surfaces. Accordingly, a surface referred to as one surface in a part of this specification may also be referred to as the other surface in other parts of this specification.

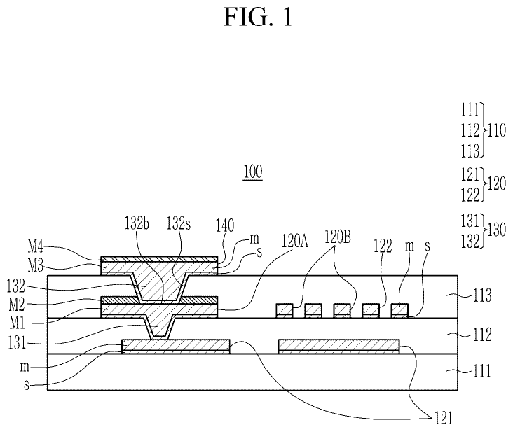

In addition, throughout this specification, the expressions “upper surfaces”, “upper sides”, “lower surfaces”, and “lower sides” are used to refer to the upper surfaces, the upper sides, the lower surfaces, and the lower sides as seen in the direction from a first insulating layer 111 toward a third insulating layer 113. For example, in FIG. 1, a second insulating layer 112 is disposed on the upper surface of the first insulating layer 111.

Hereinafter, wiring structures and semiconductor packages according to embodiments of the present disclosure will be described with reference to the drawings.

FIG. 1 is a cross-sectional view of a wiring structure according to an embodiment.

Referring to FIG. 1, a wiring structure 100 may include an insulating layer 110, a wiring layer 120 buried in the insulating layer 110, a via 130 for connecting between layers, and a connection pad 140 disposed on the insulating layer 110.

The insulating layer 110 and/or the wiring layer 120 may include (or consist of) a plurality of insulating layers 111, 112, and 113 and/or a plurality of wiring layers 121 and 122, respectively. The plurality of wiring layers 121 and 122 may be covered by the plurality of insulating layers 111, 112, and 113. For example, as shown in the drawing, the wiring structure 100 may include a first insulating layer 111, a first wiring layer 121 disposed on the first insulating layer 111, a second insulating layer 112 disposed on the first wiring layer 121 so as to cover the first wiring layer 121, a second wiring layer 122 disposed on the second insulating layer 112, and a third insulating layer 113 disposed on the second wiring layer 122 so as to cover the second wiring layer 122. However, the structure of the wiring structure 100 shown in the drawing is merely an example, and each of the numbers of insulating layers 110 and wiring layers 120 can be changed according to designs. For example, the wiring structure 100 may further include a wiring layer (not shown in the drawing) buried in the lower surface of the first insulating layer 111.

The via 130 may include a first via 131 that passes through the second insulating layer 112 so as to connect the first wiring layer 121 and the second wiring layer 122 together, and a second via 132 that passes through the third insulating layer 113 so as to connect the second wiring layer 122 and the connection pad 140 together. In the drawing, only one first via 131 is shown on the second insulating layer 112 and only one second via 132 is shown on the third insulating layer 113; however, the wiring structure 100 may include more vias. If necessary, the wiring structure 100 may further include a via (not shown in the drawing) that passes through the first insulating layer 111 so as to connect the first wiring layer 121 and another component.

The wiring structure 100 may include the connection pad 140 for electrically connecting the wiring structure 100 to an external component. The connection pad 140 may be disposed on the insulating layer 110, and may be disposed on the insulating layer 113 disposed at the top among the plurality of insulating layers 111, 112, and 113. Referring to the drawing, the connection pad 140 may be disposed on the uppermost third insulating layer 113 of the plurality of insulating layers 111, 112, and 113. In the drawing, only one connection pad 140 is shown; however, a plurality of connection pads 140 may be disposed on the third insulating layer 113 so as to be spaced apart from one another.

Further, the wiring layer 120 of the wiring structure 100 may include a wiring pad 120A that is connected to the connection pad 140 through a via 132. The wiring pad 120A may be included in the uppermost wiring layer 122 of the plurality of wiring layers 121 and 122. The uppermost wiring layer 122 may be the wiring layer 122 of the plurality of wiring layers 121 and 122 disposed closest to the connection pad 140. Referring to the drawing, the uppermost second wiring layer 122 of the plurality of wiring layers 121 and 122 may include the wiring pad 120A that is connected to the connection pad 140 through the second via 132. Referring to the drawing, the uppermost wiring layer 122 may be covered by the uppermost insulating layer 113 of the plurality of insulating layers 111, 112, and 113 that cover the plurality of wiring layers 121 and 122. By applying the wiring pad 120A covered by the uppermost insulating layer 113 to the structure, it is possible to limit and/or prevent delamination between them.

The wiring pad 120A may include a first metal layer M1 and a second metal layer M2 disposed on the first metal layer M1. The second metal layer M2 may be disposed only on a portion of the first metal layer M1, such as the peripheral portion of the first metal layer M1, so as to expose the center portion of the first metal layer M1. The center portion of the first metal layer M1 refers to an inner portion surrounded by the peripheral portion, and the peripheral portion refers to an outer portion surrounding the center portion. In the center portion of the first metal layer M1, which is a portion on which the second metal layer M2 is not disposed, the second via 132 may be disposed. Accordingly, the bottom surface 132b of the second via 132 may be in contact with the first metal layer M1, and the second metal layer M2 may surround the side surface 132s of the second via 132 abutting the bottom surface 132b. Further, the second via 132 may be positioned at a level between the first metal layer M1 and the connection pad 140.

Meanwhile, the wiring structure 100 has a structure in which the wiring pad 120A is connected to the connection pad 140 through the via 132 is different than a general wiring structure. Specifically, the wiring pad 120A includes the first metal layer M1 that abuts the bottom surface 132b of the second via 132, and the second metal layer M2 that is disposed on the first metal layer M1 and surrounds the side surface 132s abutting the bottom surface of the second via 132. As will be described below, the first metal layer M1 that abuts the bottom surface 132b of the second via 132 may be formed of a material having a low resistance value, such as copper (Cu) or the like, and the second metal layer M2 may be formed of a material having excellent adhesion to the third insulating layer 113, such as nickel (Ni) or the like. Accordingly, it is possible to provide the wiring structure 100 including the wiring pad 120A that can be electrically connected to the connection pad 140 with a low resistance value while having excellent adhesion to the insulating layer 113.

Hereinafter, the individual components of the wiring structure 100 according to the present disclosure will be described in detail.

The insulating layer 110 may cover the wiring layer 120 to protect it, and insulate the plurality of wiring layers 121 and 122 from each other.

As the material of each of the plurality of insulating layers 111, 112, and 113, insulating materials may be used, and for example, a PID (photo imageable dielectric) which is a photosensitive insulating material usable in a photoresist process may be used. However, the present disclosure is not limited thereto, and as the material of each of the plurality of insulating layers 111, 112, and 113, a thermosetting resin such as an epoxy resin, a thermoplastic resin such as a polyimide resin, and the like may be used.

Depending on the materials of the plurality of insulating layers 111, 112, and 113, the boundaries between the insulating layers 111, 112, and 113 may be unclear such that it is difficult to see the boundaries with naked eyes. Further, the materials, thicknesses, and the like of the plurality of insulating layers 111, 112, and 113 may be the same as or different from one another.

The wiring layer 120 may include wiring patterns that function as electrical signal transfer channels, a via pad for connecting to the via, and a wiring pad for connecting to the connection pad, and the like.

Each of the plurality of wiring layers 121 and 122 may include a seed layer s and at least one metal layer m disposed on the seed layer s. In this specification, the following description will be made on the assumption that when the wiring pad 120A is included in the second wiring layer 122, the first metal layer M1 includes a seed layer s and a metal layer m, and the second metal layer M2 is disposed on the metal layer m of the first metal layer M1.

The seed layers s and the metal layers m of the wiring layer 120 may be formed integrally with seed layers s and metal layers m of vias 130 that are disposed below them, and there may be no boundaries therebetween. For example, as shown in the drawing, the seed layer s and the metal layer m of the second wiring layer 122 may be formed integrally with the seed layer s and the metal layer m of the first via 131.

As the formation material of each of the plurality of wiring layers 121 and 122, specifically, the seed layers s and the metal layers m, a conductive material such as copper (Cu), aluminum (Al), silver (Ag), gold (Au), tungsten (W), zinc (Zn), or an alloy thereof may be used. The materials of the seed layers s and the metal layers m may be the same as or different from each other.

As described above, the uppermost second wiring layer 122 of the plurality of wiring layers 121 and 122 may include the wiring pad 120A for electrically connecting the connection pad 140 to the wiring layer 120. The wiring pad 120A may include the first metal layer M1 and the second metal layer M2 disposed on the first metal layer M1. The wiring pad 120A may be connected to a wiring layer disposed in another layer, for example, the first wiring layer 121, and/or be connected to a wiring pattern 120B disposed in the same layer.

The first metal layer M1 may have a circular shape as seen in a plan view. The second metal layer M2 may be disposed only on a portion of the first metal layer M1, for example, a peripheral portion including the outer periphery, so as to expose the center portion of the first metal layer M1. Each of the outer periphery and inner periphery of the second metal layer M2 may have a circular shape as seen in a plan view. Further, the outer periphery of the first metal layer M1 and the outer periphery of the second metal layer M2 may overlap each other, but are not limited thereto.

The first metal layer M1 may contain a conductive material having a low resistance value, such as copper (Cu), aluminum (Al), silver (Ag), gold (Au), tungsten (W), zinc (Zn), or an alloy thereof.

The second metal layer M2 may contain a conductive material having excellent adhesion to the insulating layer 113, such as nickel (Ni).

The thickness of the second metal layer M2 is smaller than the thickness of the second via 132, and the second metal layer M2 surrounds only the area of the side surface 132s of the second via 132 abutting the bottom surface 132b, and does not surround the area abutting the upper surface of the second via 132. The third insulating layer 113 is disposed on the second metal layer M2, and the second metal layer M2 is connected to the connection pad 140 through the second via 132 but is not in direct contact with the connection pad 140.

Further, the thickness of the second metal layer M2 may be smaller than the thickness of the first metal layer M1, but is not limited thereto, and may be larger than or equal to the thickness of the first metal layer M1.

The second wiring layer 122 may further include the wiring pattern 120B. The wiring pattern 120B may be used as an electrical signal transfer channel, and may include various patterns such as signal patterns, a power pattern, a ground pattern, and the like. The wiring pattern 120B may or may not be connected to the wiring pad 120A.

The wiring pattern 120B may include the first metal layer M1, but may include no second metal layer M2. Accordingly, the first metal layer M1 included in the wiring pattern 120B may cover the third insulating layer 113. Further, the thickness of the wiring pattern 120B may be smaller than the thickness of the wiring pad 120A.

As described above, the second metal layer M2 may be selectively formed only on the first metal layer M1 of the wiring pad 120A that is connected to the connection pad 140, whereby it is possible to limit and/or minimize an increase in the complexity of the process and an increase in the manufacturing cost. However, if necessary, the second metal layer M2 may also be formed on the first metal layer M1 of the wiring pattern 120B.

Meanwhile, it goes without saying that the first wiring layer 121 may also include wiring patterns, a via pad, a wiring pad, and the like.

The via 130 may be used as an electrical connecting path between components disclosed in different layers.

The via 130 may have a tapered shape that narrows as it goes from top to bottom, but is not limited thereto, and may have a columnar shape. Although the diameter of the via 130 is not particularly limited, the diameter of the second via 132 that is connected to the connection pad 140 may be larger than those of other vias, for example, the diameter of the first via 131.

The via 130 may include a seed layer s and at least one metal layer m disposed on the seed layer s. The seed layer s and the metal layer m of the via 130 may be formed integrally with the wiring layer 120 or the connection pad 140 disposed thereon, and there may be no boundaries therebetween. For example, as described above, the seed layer s and the metal layer m of the first via 131 may be formed integrally with the seed layer s and the metal layer m of the wiring pad 120A included in the second wiring layer 122. Further, the seed layer s and the metal layer m of the second via 132 may be formed integrally with the seed layer s and the metal layer m of the connection pad 140.

Even as the formation material of each of the seed layer s and the metal layer m of the via 130, a conductive material such as copper (Cu), aluminum (Al), silver (Ag), gold (Au), tungsten (W), zinc (Zn), or an alloy thereof may be used. The materials of the seed layers s and the metal layers m may be the same as or different from each other.

The connection pad 140 may electrically connect the wiring structure 100 to another component.

The connection pad 140 may include a third metal layer M3, and may further include a fourth metal layer M4 disposed on the third metal layer M3.

The third metal layer M3 may include a seed layer s and at least one metal layer m disposed on the seed layer s. Further, the fourth metal layer M4 may be disposed on the metal layer m of the third metal layer M3.

As described above, the seed layer s and the metal layer m of the connection pad 140 may be formed integrally with the seed layer s and the metal layer m of the second via 132 disposed below them, and there may be no boundaries therebetween.

As the formation material of each of the seed layer s and the metal layer m of the connection pad 140, a conductive material such as copper (Cu), aluminum (Al), silver (Ag), gold (Au), tungsten (W), zinc (Zn), or an alloy thereof may be used. The materials of the seed layers s and the metal layers m may be the same as or different from each other.

The fourth metal layer M4 may limit and/or prevent corrosion and oxidation of the metal in the third metal layer M3, and may provide excellent electrical connecting and reliable signal transfer between the connection pad 140 and a component that is connected thereto.

Even as the material of the fourth metal layer M4, a conductive material may be used, and in the above-mentioned aspect; for example, the fourth metal layer M4 may contain gold (Au), tin (Sn), or zinc (Zn).

The fourth metal layer M4 may be a thin metal film having a small thickness (e.g., 100 nm or less, 50 nm or less).

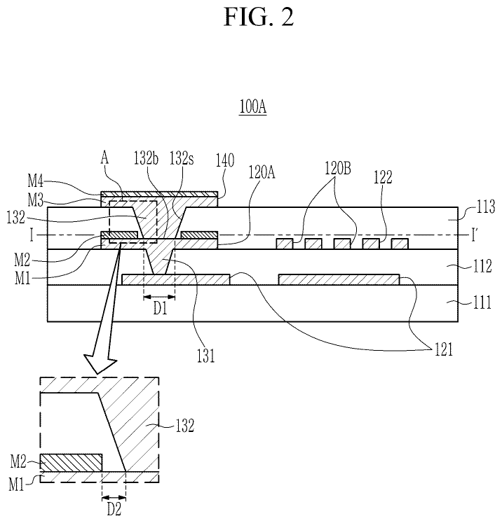

FIG. 2 is a cross-sectional view of a wiring structure according to an embodiment.

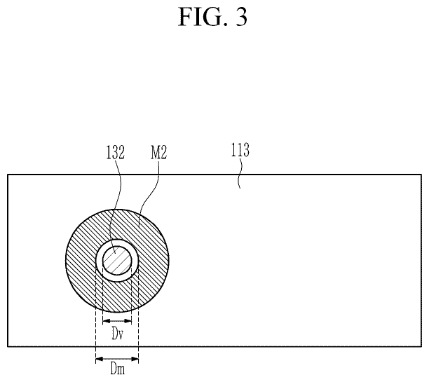

FIG. 3 is a cross-sectional plan view of the wiring structure shown in FIG. 2, taken along line I-I′.

In FIG. 2 and FIG. 3, the seed layers s and the metal layers m are omitted.

In a wiring structure 100A according to an embodiment, the third insulating layer 113 may fill the space between second metal layer M2 and the side surface 132s of the second via 132. Accordingly, the second metal layer M2 may be spaced apart from the second via 132 by the third insulating layer 113.

During manufacturing of the wiring structure 100A, when a via hole for forming the second via 132 is formed so as to have a small diameter, the second via 132 may be spaced apart from the second metal layer M2 without contact with it.

When the diameter of the bottom surface 132b of the second via 132 is denoted by D1, and the difference between the inside diameter Dm of the second metal layer M2 and the diameter Dv of the second via 132 at the level of the boundary between the first metal layer M1 and the second metal layer M2 is denoted by D2, the value of D2/D1 may be equal to or smaller than 0.05. Within the above-mentioned numerical range, it is possible to secure sufficient adhesion between the wiring pad 120A and the third insulating layer 113. In this case, the difference between the inside diameter Dm of the second metal layer M2 and the diameter Dv of the second via 132 may be equal to the distance between the inside diameter of the second metal layer M2 and the via 132. The inside diameter Dm of the second metal layer M2 may correspond to the outside diameter of the second via 132, and the inner periphery of the second metal layer M2 may surround the side surface 132s of the second via 132.

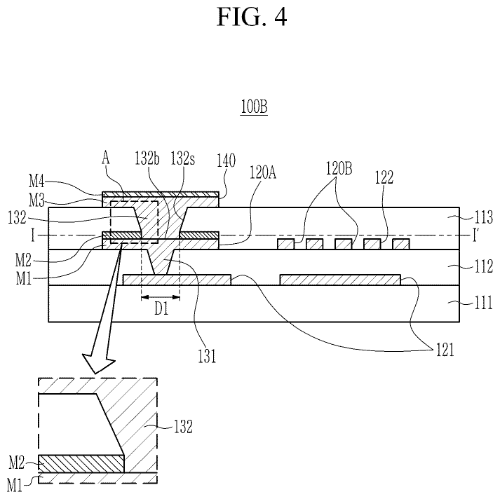

FIG. 4 is a cross-sectional view of a wiring structure according to an embodiment.

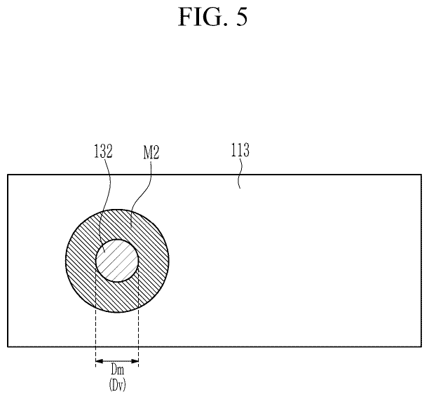

FIG. 5 is a cross-sectional plan view of the wiring structure shown in FIG. 4, taken along line I-I′.

In a wiring structure 100B according to an embodiment, the second metal layer M2 may be in contact with the side surface 132s of the via 132.

During manufacturing of the wiring structure 100B, when a via hole for forming the second via 132 is formed so as to have a diameter larger than that in the wiring structure 100A, the second via 132 may be formed so as to be in contact with the second metal layer M2.

At a level between the upper surface and lower surface of the second metal layer M2, the diameter Dv of the second via 132 and the diameter Dm of the second metal layer M2 may be the same. Further, at a level between the upper surface and lower surface of the second metal layer M2, the diameter Dv of the second via 132 and the diameter Dm of the second metal layer M2 may also be equal to the diameter D1 of the bottom surface of the second via 132.

On the second metal layer M2, the diameter Dv of the second via 132 may decrease as it goes from the connection pad 140 toward the wiring pad 120A, and in the area surrounded by the second metal layer M2, the diameter Dv of the second via 132 may be substantially constant. As will be described below, the second metal layer M2 may be formed by exposing and developing a photoresist layer, and the via hole of the second via 132 may be formed by exposing and developing a photosensitive insulating material such as a PID or the like, and due to the material difference between the photoresist layer and the third insulating layer 113, the diameter Dv of the second via 132 may have the above-described structure.

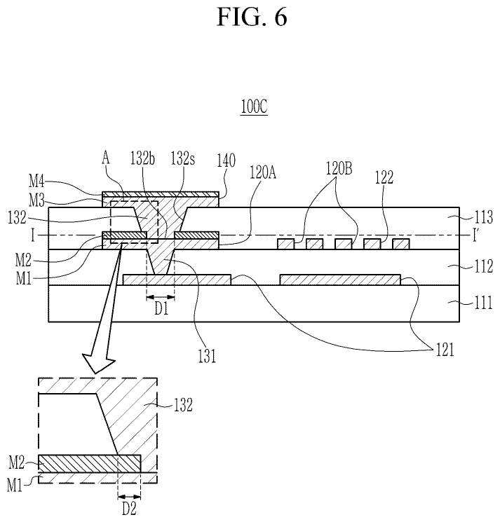

FIG. 6 is a cross-sectional view of a wiring structure according to an embodiment.

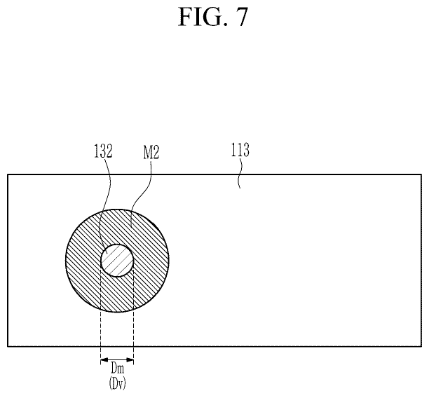

FIG. 7 is a cross-sectional plan view of the wiring structure shown in FIG. 6, taken along line I-I′.

In a wiring structure 100C according to an embodiment, the second metal layer M2 may abut the side surface 132s of the via 132, and the via 132 may cover a portion of the upper surface of the second metal layer M2.

During manufacturing of the wiring structure 100C, when a via hole for forming the second via 132 is formed so as to have a diameter larger than that in the wiring structure 100B, the via hole may expose the upper surface of the second metal layer M2, and the second via 132 may cover a portion of the upper surface of the second metal layer M2.

When the diameter of the bottom surface 132b of the second via 132 is denoted by D1, and the difference between the diameter Dv of the second via 132 and the inside diameter Dm of the second metal layer M2 at the level where the upper surface of the second metal layer M2 is positioned is denoted by D2, the value of D2/D1 may be equal to or smaller than 0.05. Within the above-mentioned numerical range, it is possible to limit and/or prevent the second metal layer M2 from excessively overlapping the second via 132, thereby limiting and/or preventing an increase the resistance between the wiring pad 120A and the connection pad 140. In this case, the difference between the diameter Dv of the second via 132 and the inside diameter Dm of the second metal layer M2 may be equal to the distance between the second via 132 and the inner periphery of the second metal layer M2.

On the second metal layer M2, the diameter Dv of the second via 132 may decrease as it goes from the connection pad 140 toward the wiring pad 120A, and in the area surrounded by the second metal layer M2, the diameter Dv of the second via may be substantially constant. As will be described below, the second metal layer M2 may be formed by exposing and developing a photoresist layer, and the via hole of the second via 132 may be formed by exposing and developing a photosensitive insulating material such as a PID or the like, and due to the material difference between the photoresist layer and the third insulating layer 113, the diameter Dv of the second via 132 may have the above-described structure.

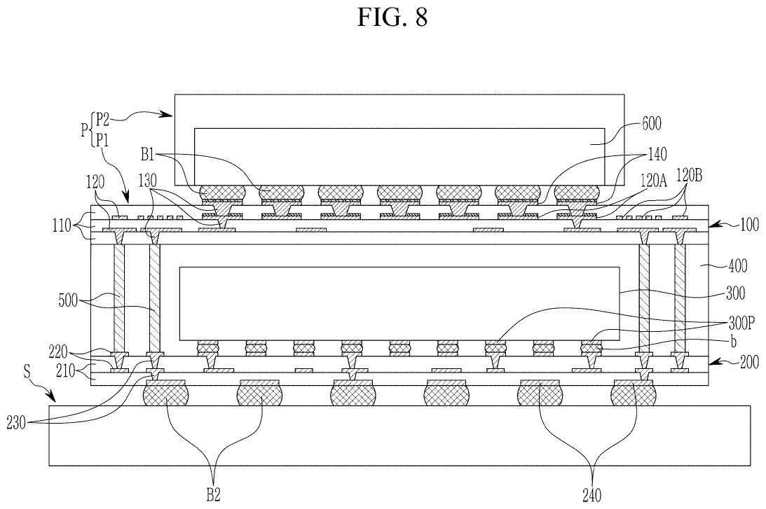

FIG. 8 is a cross-sectional view of a semiconductor package according to an embodiment.

A semiconductor package P may include a first semiconductor package P1 and a second semiconductor package P2 disposed on the first semiconductor package P1.

The first semiconductor package P1 may include a first wiring structure 200, a first semiconductor chip 300 that is disposed on the first wiring structure 200 so as to be electrically connected to the first wiring structure 200, a sealing material 400 that is disposed on the first wiring structure 200 so as to encapsulate the first semiconductor chip 300, a second wiring structure 100 that is disposed on the sealing material 400, and conductive posts 500 that passes through the sealing material 400 so as to electrically connect the first wiring structure 200 and the second wiring structure 100 together.

The first wiring structure 200 may include an insulating layer 210, a wiring layer 220, a via 230, and a connection pad 240.

The insulating layer 210 and/or the wiring layer 220 may include (or consist of) a plurality of insulating layers 210 and/or a plurality of wiring layers 220, respectively. The plurality of wiring layers 220 may be covered by the plurality of insulating layers 210, respectively.

The insulating layer 210 may cover the wiring layer 220 to protect it, and may insulate the plurality of wiring layers 220 from one another.

As the material of each of the plurality of insulating layers 210, insulating materials may be used, and for example, a PID (photo imageable dielectric) which is a photosensitive insulating material usable in a photoresist process may be used. However, the present disclosure is not limited thereto, and as the material of each of the plurality of insulating layers 210, a thermosetting resin such as an epoxy resin, a thermoplastic resin such as a polyimide resin, and the like may be used.

Depending on the materials of the plurality of insulating layers 210, the boundaries between the insulating layers 210 may be unclear such that it is difficult to see the boundaries with the naked eyes. Further, the materials, thicknesses, and the like of the plurality of insulating layers 210 may be the same as or different from one another.

The wiring layer 220 may be disposed on the insulating layer 210, and may be covered by an insulating layer 210 disposed in another layer. For example, as shown in the drawing, the wiring layer 220 may be disposed on the upper surface of the insulating layer 210, and be covered by an insulating layer 210 disposed in another layer. However, the uppermost wiring layer 220 may be covered by the sealing material 400, not by an insulating layer 210.

As the formation material of each of the plurality of wiring layers 220, a conductive material such as copper (Cu), aluminum (Al), silver (Ag), gold (Au), tungsten (W), zinc (Zn), or an alloy thereof may be used.

The via 230 may pass through the insulating layer 210 and be used as an electrical connecting path between components disclosed in different layers.

The via 230 may have a tapered shape that narrows as it goes from top to bottom, but is not limited thereto, and may have a columnar shape. The via 230 may be formed integrally with the wiring layer 220 disposed thereon, and there may be no boundary therebetween.

Even as the formation material of the via 230, similar to the wiring layer 220, a conductive material such as copper (Cu), aluminum (Al), silver (Ag), gold (Au), tungsten (W), zinc (Zn), or an alloy thereof may be used.

The connection pad 240 may electrically connect the first wiring structure 200 to another component. For example, the connection pad 240 may electrically connect the first wiring structure 200 to a substrate S.

As shown in the drawing, the connection pad 240 may be buried in the insulating layer 210 so as to be exposed from the lower surface of the insulating layer 210, but may be disposed on the lower surface of the insulating layer 210.

Even as the formation material of the connection pad 240, similar to the wiring layer 220, a conductive material such as copper (Cu), aluminum (Al), silver (Ag), gold (Au), tungsten (W), zinc (Zn), or an alloy thereof may be used.

The first semiconductor chip 300 may include an application processor (AP) chip, but is not limited thereto, and may also include other types of semiconductor chips, such as a central processing unit (CPU), a graphic processing unit (GPU), a logic chip, a system on chip (SoC), and the like.

The first semiconductor chip 300 may include connection pads 300P, and may be disposed in a face-down form such that the connection pads 300P face the first wiring structure 200.

Further, the first semiconductor package P1 may further include conductive bumps b that are disposed between the first semiconductor chip 300 and the first wiring structure 200, and the connection pads 300P of the first semiconductor chip 300 may be physically and electrically connected to a wiring layer 210 of the first wiring structure 200 through the conductive bumps b. The conductive bumps b may be micro solder bumps, but are not limited thereto.

The sealing material 400 may physically, chemically, and mechanically protect the first semiconductor chip 300. The sealing material 400 may cover the side surfaces and upper surface of the first semiconductor chip 300. Depending on designs, the sealing material 400 may cover only the side surfaces of the first semiconductor chip 300, and the upper surface of the first semiconductor chip 300 may be exposed from the sealing material 400.

As the formation material of the sealing material 400, an epoxy mold compound (EMC) and the like may be used, and as the method of forming the sealing material 400, a well-known method such as compression molding, transfer molding, or the like may be used.

The second wiring structure 100 may be disposed on the sealing material 400 so as to electrically connect the first semiconductor package P1 and the second semiconductor package P2 together.

The second wiring structure 100 in FIG. 8 may be the same as the wiring structure 100 in FIG. 1 or may have the structure of any one of the wiring structures 100A, 100B, or 100C according to the embodiments in FIGS. 2-3, 4-5, and 6-7. As described above, the second wiring structure 100 may include connection pads 140, and the connection pads 140 may electrically connect the second wiring structure 100 to the second semiconductor package P2.

Further, the semiconductor package P may further include conductive bumps B1 that are disposed between the second semiconductor package P2 and the connection pads 140, and the second semiconductor package P2 and the connection pads 140 may be physically and electrically connected through the conductive bumps B1. The conductive bumps B1 may be solder balls, but are not limited thereto.

Each component of the second wiring structure 100 is as described above, and thus a detailed description thereof will not be made.

The conductive posts 500 may electrically connect the first wiring structure 200 and the second wiring structure 100 together.

Even as the formation material of the conductive posts 500, a conductive material may be used, and for example, copper (Cu), aluminum (Al), silver (Ag), gold (Au), tungsten (W), zinc (Zn), or an alloy thereof may be used.

The second semiconductor package P2 may include a second semiconductor chip 600.

Further, the second semiconductor package P2 may further include a substrate (not shown in the drawing) on which the second semiconductor chip 600 is mounted, a sealing material that encapsulates the second semiconductor chip, etc. Alternatively, in place of the second semiconductor package P2, the second semiconductor chip 600 not separately packaged may be disposed on the first semiconductor package P1.

The second semiconductor chip 600 may include various types of memory chips such as DRAMs, SRAMs, flash memories, etc., but is not limited thereto.

The semiconductor package P may be mounted on the substrate S such as a main board. Between the semiconductor package P and the substrate S, conductive bumps B2 such as solder balls may be disposed, and the semiconductor package P and the substrate S may be physically and electrically connected through the conductive bumps B2.

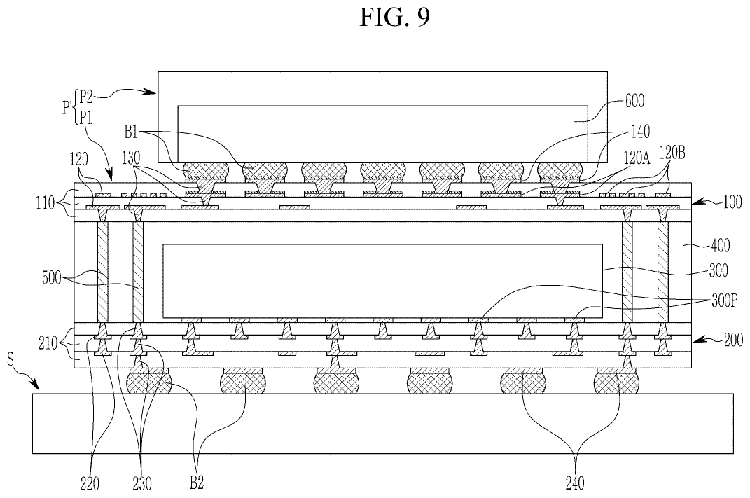

FIG. 9 is a cross-sectional view of a semiconductor package according to an embodiment.

A semiconductor package P′ according to an embodiment is different from the semiconductor package P according to the embodiment in the first wiring structure 200.

Specifically, each of the wiring layers 220 may be disposed on the lower surface of an insulating layer 210, and the vias 230 may have a tapered shape that narrows as it goes from the lower side toward the upper side.

Further, the first semiconductor chip 300 may be directly connected to the first wiring structure 200 without conductive bumps, and the connection pads 300P of the first semiconductor chip 300 may be connected to the wiring layer 220 through the vias 230. In the technical field to which the present disclosure belongs, the first semiconductor package P1 may be referred to as a fan-out wafer level package (FOWLP), a fan-out panel level package (FOPLP), or the like.

The other components are identical to those in the semiconductor package P according to the embodiment described above, and thus a detailed description thereof will not be made.

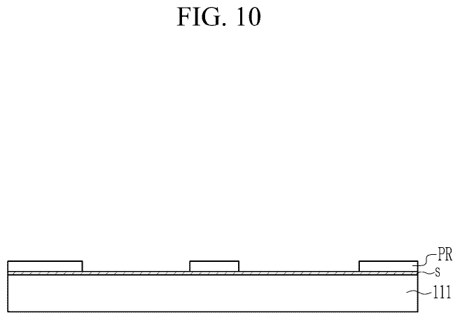

FIG. 10 to FIG. 23 are views illustrating wiring structure manufacturing processes according to some embodiments of the present disclosure.

A manufacturing method of the wiring structure 100 may include an operation of forming the plurality of insulating layers 111, 112, and 113, the plurality of wiring layers 121 and 122, the via 130, and the connection pad 140. Particularly, the manufacturing method of the wiring structure 100 includes an operation of forming the wiring pad 120A including the first metal layer M1 and the second metal layer M2, an operation of forming the insulating layer 113 on the wiring pad 120A, an operation of forming the via 132 such that the via passes through the insulating layer 113 so as to be connected to the center portion of the first metal layer M1, and an operation of forming the connection pad 140 on the insulating layer 113 such that the connection pad is connected to the via 132.

The operation of forming the wiring pad 120A may include an operation of forming the first metal layer M1, and an operation of forming the second metal layer M2 on the first metal layer M1 such that the center portion of the first metal layer M1 is exposed.

The operation of forming the via 132, the via 132 may be formed so as to be spaced apart from the second metal layer M2 without contact with it, and in this case, the wiring structure 100 shown in FIG. 2 may be formed. Alternatively, in the operation of forming the via 132, the via 132 may be formed so as to be in contact with the second metal layer M2, and in this case, the wiring structure 100B shown in FIG. 4 or the wiring structure 100C shown in FIG. 6 may be formed.

In the operation of forming the connection pad 140, the connection pad 140 may be formed integrally with the via 132.

Hereinafter, an example manufacturing method of the wiring structure 100 according to the embodiment will be described in detail with reference to the drawings.

First, referring to FIG. 10, the first insulating layer 111 may be formed, the seed layer s for forming the first wiring layer 121 may be formed on the first insulating layer 111, and a photoresist layer PR for forming the metal layer m may be formed on the seed layer s.

The first insulating layer 111 may be formed, for example, by applying a PID which is a photosensitive insulating material and curing it; and if necessary, a process of exposing and developing the applied PID for pattern formation may be additionally performed.

The seed layer s may be formed by physical vapor deposition (PVD), chemical vapor deposition (CVD), or the like, and may be formed in the form of a thin metal film on the first insulating layer 111.

The photoresist layer PR may be formed by applying a photoresist to the upper surface of the seed layer s and performing pattern formation (patterning) by exposure and development. The photoresist layer PR may be patterned so as to have an opening in an area of the seed layer s where the metal layer m is to be formed. After forming the pattern in the photoresist layer PR, a descum process of removing the residues (scum) of the photoresist may be additionally performed.

As the photoresist, any photoresist commonly used in the semiconductor industry may be used. The photoresist may be any one of a positive type in which exposed areas are removed and a negative type in which exposed areas are left.

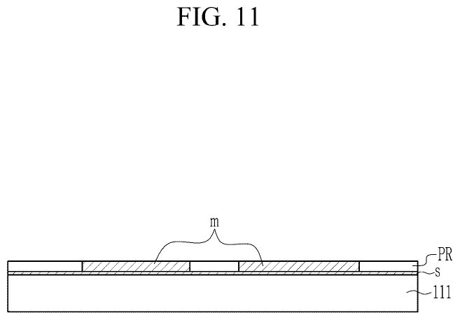

Next, referring to FIG. 11, the metal layer m is formed on the seed layer s. The metal layer m may be formed by, for example, electroplating, and may be formed by filling the opening in the photoresist layer PR.

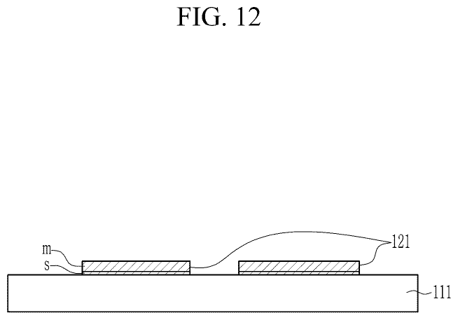

Subsequently, referring to FIG. 12, the first wiring layer 121 may be formed by removing the photoresist layer PR and etching the seed layer s.

The photoresist layer PR may be removed by stripping, whereby the seed layer s not covered by the metal layer m may be exposed so that etching can be performed on the seed layer. Further, a descum process of removing the residues of the photoresist may be additionally performed.

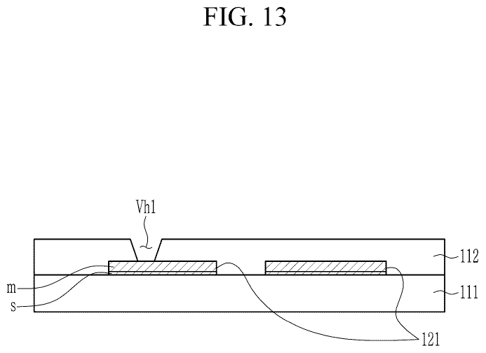

Next, referring to FIG. 13, the second insulating layer 112 may be formed on the first wiring layer 121, and a first via hole Vh1 for forming the first via 131 may be formed.

The second insulating layer 112 may be formed by applying a PID, which is a photosensitive insulating material, forming a pattern for forming the first via hole Vh1 by exposure and development, and curing the PID. However, the present disclosure is not limited thereto, and the first via hole Vh1 may also be formed by laser processing or the like. The first via hole Vh1 may expose a portion of the first wiring layer 121 connected thereto.

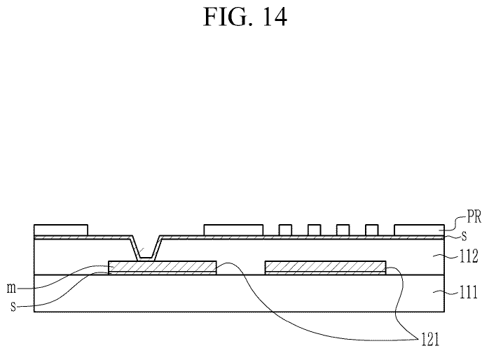

Subsequently, referring to FIG. 14, the seed layer s for forming the first via 131 and the second wiring layer 122 may be formed, and a photoresist layer PR for forming the metal layer m on the seed layer s may be formed.

The seed layer s may be formed by physical vapor deposition (PVD), chemical vapor deposition (CVD), or the like, and may be formed in the form of a thin metal film on the upper surface of the second insulating layer 112, the wall surface of the first via hole Vh1, and the exposed first wiring layer 121.

The photoresist layer PR may be patterned so as to have openings in areas where the metal layer m for the wiring pad 120A and the wiring pattern 120B is to be formed. In addition, the formation method and type of the photoresist layer PR are the same as described above, and thus a detailed description thereof will not be made.

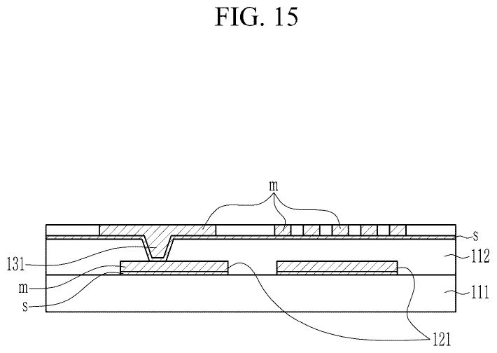

Subsequently, referring to FIG. 15, the metal layer m is formed on the seed layer s. The metal layer m may be formed by, for example, electroplating, and may be formed by filling the opening in the photoresist layer PR.

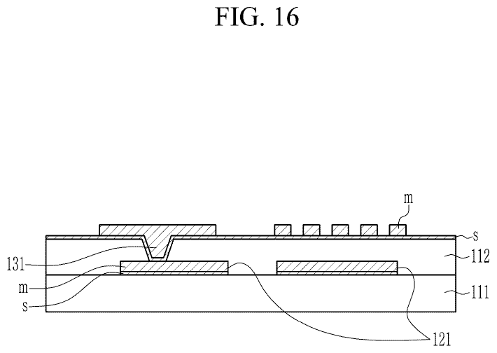

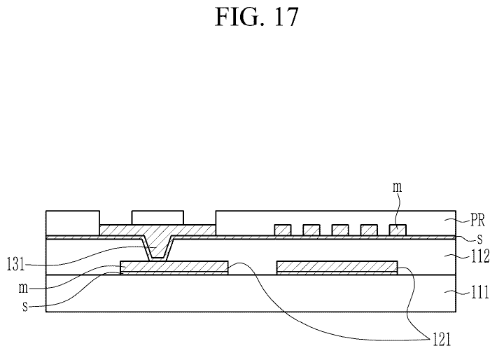

Next, referring to FIG. 16 and FIG. 17, after the photoresist layer PR may be removed by stripping, a photoresist layer PR is formed again on the seed layer s and the metal layer m to form the second metal layer M2. The photoresist layer PR may be patterned so as to have openings in areas where the second metal layer M2 is to be formed. In addition, the formation method and type of the photoresist layer PR are the same as described above, and thus a detailed description thereof will not be made.

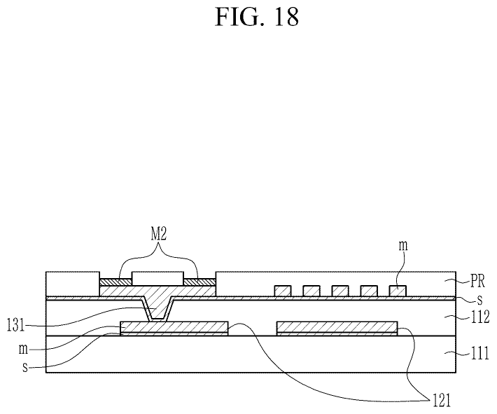

Subsequently, referring to FIG. 18, the second metal layer M2 is formed on the metal layer m. At this time, in areas where the wiring pad 120A is not to be formed, including the areas where the wiring pattern 120B is to be formed, the metal layer m may be covered by the photoresist layer PR. Accordingly, only in the area where the wiring pad 120A is to be formed, the second metal layer M2 may be selectively formed. The second metal layer M2 may be formed so as to expose the center portion of the first metal layer M1 which is an area where the second via 132 is to be formed. By the way, the seed layer s formed around the first metal layer M1 may be removed after the operation of forming the second metal layer M2, and when the second metal layer M2 is formed, the seed layer s of the first metal layer M1 may be integrated with the surrounding seed layer s. The second metal layer M2 may be formed by, for example, electroplating, and may be formed by filling the opening in the photoresist layer PR.

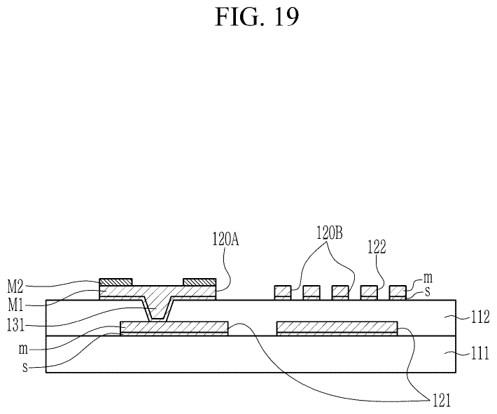

Next, referring to FIG. 19, the second wiring layer 122 including the wiring pad 120A and the wiring pattern 120B may be formed by removing the photoresist layer PR and etching the seed layer s.

The photoresist layer PR may be removed by stripping, whereby the seed layer s not covered by the metal layer m may be exposed so that etching can be performed on the seed layer. Further, a descum process of removing the residues of the photoresist may be additionally performed.

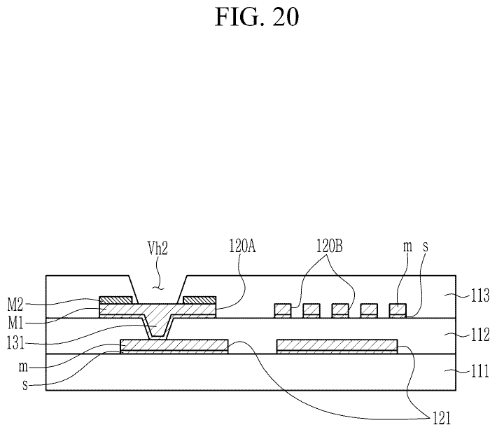

Subsequently, referring to FIG. 20, the third insulating layer 113 may be formed on the second wiring layer 122, and a second via hole Vh2 for forming the second via 132 may be formed.

The third insulating layer 113 may be formed by applying a PID which is a photosensitive insulating material, forming a pattern for forming the second via hole Vh2 by exposure and development, and curing the PID. However, the present disclosure is not limited thereto, and the second via hole Vh2 may also be formed by laser processing or the like. The second via hole Vh2 may expose the wiring pattern 120B connected thereto, specifically, a portion of the first metal layer M1 of the wiring pattern 120B, for example, the center portion.

The second via hole Vh2 may further expose the inner surface of the second metal layer M2 depending on its diameter, and may further expose a portion of the inner surface and upper surface of the second metal layer M2, for example, an area of the upper surface abutting the inner periphery. In this case, the wiring structure 100B shown in FIG. 4 or the wiring structure 100C shown in FIG. 6 may be formed.

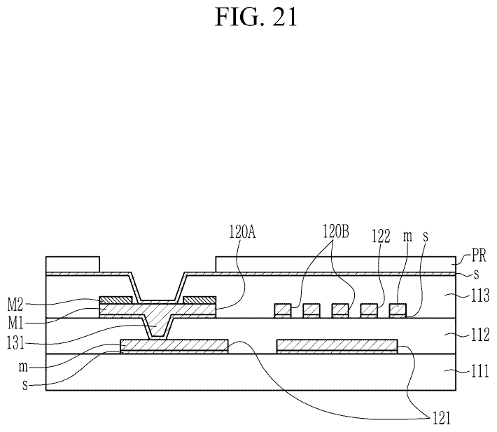

Next, referring to FIG. 21, the seed layer s for forming the second via 132 and the connection pad 140 may be formed, and a photoresist layer PR for forming the metal layer m on the seed layer s may be formed.

The seed layer s may be formed by physical vapor deposition (PVD), chemical vapor deposition (CVD), or the like, and may be formed in the form of a thin metal film on the upper surface of the third insulating layer 113, the wall surface of the second via hole Vh2, and the exposed first metal layer M1 of the wiring pad 120A.

As shown in the drawing, when the second via hole Vh2 exposes only the first metal layer M1, the second via 132 may be formed so as to be spaced apart from the second metal layer M2 without contact with it. When the second via hole Vh2 further exposes either the inner surface of the second metal layer M2 or the inner surface and the upper surface, the seed layer s may also be formed on either the inner surface of the second metal layer M2 or the inner surface and the upper surface. Accordingly, the via 132 may be formed so as to be in contact with the second metal layer M2.

The photoresist layer PR may be patterned so as to have an opening in an area where the metal layer m of the connection pad 140 is to be formed. In addition, the formation method and type of the photoresist layer PR are the same as described above, and thus a detailed description thereof will not be made.

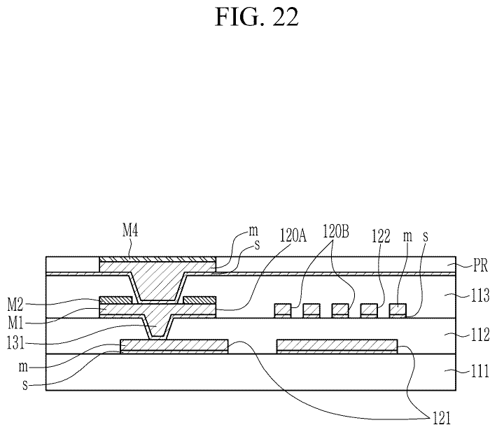

Subsequently, referring to FIG. 22, on the seed layer s, the metal layer m and the fourth metal layer M4 are formed. The metal layer m and the fourth metal layer M4 may be sequentially formed by, for example, electroplating, and may be formed by filling the opening in the photoresist layer PR. When the metal layer m and the fourth metal layer M4 are formed, the same photoresist layer PR may be used. Accordingly, the metal layer m of the third metal layer M3 and the fourth metal layer M4 may have the same diameter and overlap each other.

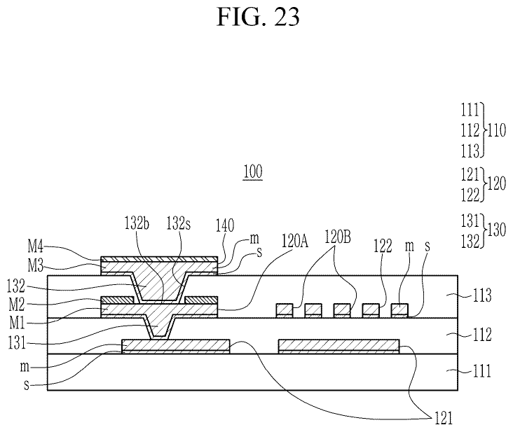

Finally, referring to FIG. 23, the connection pad 140 may be formed by removing the photoresist layer PR and etching the seed layer s.

The photoresist layer PR may be removed by stripping, whereby the seed layer s not covered by the metal layer m may be exposed so that etching can be performed on the seed layer. Further, a descum process of removing the residues of the photoresist may be additionally performed.

One or more of the elements disclosed above may be included or may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A wiring structure comprising:
a wiring layer including a wiring pad;
an insulating layer on the wiring layer and covering the wiring layer;
a connection pad on the insulating layer; and
a via passing through the insulating layer and connecting the wiring pad and the connection pad, wherein
the wiring pad includes a first metal layer and a second metal layer on the first metal layer, and
a bottom surface of the via abuts the first metal layer, and
the second metal layer surrounds a side surface of the via and is adjacent to the bottom surface of the via.

2. The wiring structure of claim 1, wherein
the insulating layer fills a space between the second metal layer and the side surface of the via.

3. The wiring structure of claim 2, wherein
D1 is a diameter of the bottom surface of the via,
D2 is a difference between an inside diameter of the second metal layer and a diameter of the via at a level of a boundary of the first metal layer and the second metal layer, and
D2/D1 is equal to or smaller than 0.05.

4. The wiring structure of claim 1, wherein
the second metal layer is in contact with the side surface of the via.

5. The wiring structure of claim 4, wherein
the via covers a portion of an upper surface of the second metal layer.

6. The wiring structure of claim 5, wherein
D1 is diameter of the bottom surface of the via,
D2 is a difference between a diameter of the via and an inside diameter of the second metal layer at a level where the upper surface of the second metal layer is positioned, and
D2/D1 is equal to or smaller than 0.05.

7. The wiring structure of claim 4, wherein
on the second metal layer, a diameter of the via decreases as it goes from the connection pad toward the wiring pad, and
in an area surrounded by the second metal layer, the diameter of the via is constant.

8. The wiring structure of claim 1, wherein
the second metal layer contains nickel (Ni).

9. The wiring structure of claim 1, wherein
the wiring layer further includes a wiring pattern including the first metal layer, and
the first metal layer in the wiring pattern is covered by the insulating layer.

10. The wiring structure of claim 1, wherein
the wiring layer and the insulating layer are among a plurality of wiring layers and a plurality of insulating layers, respectively, the
the wiring pad is in an uppermost wiring layer of the plurality of wiring layers, and
the wiring pad is covered by an uppermost insulating layer of the plurality of insulating layers such that the insulating layer is the uppermost insulating layer of the plurality of insulating layers.

11. A semiconductor package comprising:
a first semiconductor package including a first wiring structure, a first semiconductor chip on the first wiring structure and electrically connected to the first wiring structure, a sealing material on the first wiring structure and encapsulating the first semiconductor chip, a second wiring structure on the sealing material, and conductive posts passing through the sealing material and electrically connecting the first wiring structure and the second wiring structure together; and
a second semiconductor package on the first semiconductor package and including a second semiconductor chip, wherein
the second wiring structure includes a wiring layer including a wiring pad, an insulating layer on the wiring layer and covering the wiring layer, a connection pad on the insulating layer, and a via passing through the insulating layer and connecting the wiring pad and the connection pad together,
the wiring pad includes a first metal layer and a second metal layer on the first metal layer,
a bottom surface of the via is in contact with the first metal layer,
the second metal layer surrounds a side surface of the via adjacent to the bottom surface, and
the connection pad electrically connects the second semiconductor package and the second wiring structure together.

12. The semiconductor package of claim 11, further comprising:
a conductive bump between the second semiconductor package and the connection pad.

13. The semiconductor package of claim 11, wherein
the first semiconductor chip includes an application processor (AP) chip, and
the second semiconductor chip includes a memory chip.

14. The semiconductor package of claim 11, wherein
the insulating layer fills a space between the second metal layer and the side surface of the via.

15. The semiconductor package of claim 11, wherein
the second metal layer is in contact with the side surface of the via.

16. The semiconductor package of claim 15, wherein
the via covers a portion of an upper surface of the second metal layer.

17. The semiconductor package of claim 11, wherein
the second wiring structure further includes a wiring pattern,
the wiring pattern includes the first metal layer, and
the first metal layer included in the wiring pattern is covered by the insulating layer.

18. A manufacturing method for a wiring structure, the method comprising:
forming a wiring pad, the wiring pad including a first metal layer and a second metal layer on the first metal layer, the second metal layer exposing a center portion of the first metal layer;
forming an insulating layer on the wiring pad;
forming a via passing through the insulating layer and connecting to the center portion of the first metal layer; and
forming a connection pad on the insulating layer and connected to the via.

19. The manufacturing method for the wiring structure according to claim 18, wherein
the forming the via includes forming the via spaced apart from the second metal layer.

20. The manufacturing method for the wiring structure according to claim 18, wherein
the forming the via includes forming the via in contact with the second metal layer.
